(19) United States
(12) Patent Application Publication
(10) Pub. No.: US 2024/0074134 A1
(43) Pub. Date: Feb. 29, 2024

(54) METHOD FOR MANUFACTURING AN INTEGRATED CIRCUIT AND CORRESPONDING INTEGRATED CIRCUIT

(71) Applicant: STMicroelectronics (Rousset) SAS, Rousset (FR)

(72) Inventors: Paul DEVOGE, Aix-en-Provence (FR); Abderrezak MARZAKI, Aix en Provence (FR); Franck JULIEN, La Penne sur Huveaune (FR); Alexandre MALHERBE, Trets (FR)

(73) Assignee: STMicroelectronics (Rousset) SAS, Rousset (FR)

(21) Appl. No.: 18/230,952

(22) Filed: Aug. 7, 2023

(30) Foreign Application Priority Data
Aug. 25, 2022 (FR) 2208512

(51) Int. Cl. H10B 10/00; H01L 29/66; H01L 29/788

(52) U.S. Cl. CPC H10B 10/12; H01L 29/66825; H01L 29/788

(57) ABSTRACT

An integrated circuit includes transistor. That transistor is manufactured using a process including the following steps: forming a first gate region; depositing dielectric layers accumulating on sides of the first gate region to form regions of spacers having a width; etching to remove a part of the deposited dielectric layers accumulated on the sides of the first gate region to reduce the width of the regions of spacers; performing a first implantation of dopants aligned on the regions of spacers to form first lightly doped conduction regions of the transistor; and performing a second implanting of dopants to form first more strongly doped conduction regions of the transistor.

### PRIORITY CLAIM

This application claims the priority benefit of French Application for Patent No. 2208512, filed on Aug. 25, 2022, the content of which is hereby incorporated by reference in its entirety to the maximum extent allowable by law.

### TECHNICAL FIELD

Embodiments and implementations relate to integrated circuits, in particular the manufacturing of a transistor configured for operation in and over a first range of voltages in cointegration with steps for manufacturing at least one other transistor configured for operation in and over another range of voltages.

### BACKGROUND

Cointegration allows to reuse manufacturing steps provided for elements typically present in one type of integrated circuit, in order to manufacture a particular element without additional steps or additional cost.

For example, in an integrated circuit including a non-volatile memory, floating-gate transistors are typically provided to store data in memory, transistors configured for operation in a “high-voltage” range of voltages are typically provided for the operations of writing in memory, and transistors configured for operation in a “low-voltage” range of voltages are typically provided to schedule the operation of the memory, in a logic circuit of the state machine type.

Typically, in an inexpensive circuit of this type including a non-volatile memory, no particular architecture of transistors configured for operation in a first “medium-voltage” range of voltages is proposed, for reasons of cost, and only low-voltage or high-voltage architectures of transistors exist. The medium-voltage range is, for example, greater than the low-voltage range and lower than the high-voltage range, and is intended for communications of general-use signals such as input-output signals of the integrated circuit.

Conventionally, to manufacture at lesser cost a transistor configured for operation in the medium-voltage range and without introducing additional steps, a high-voltage transistor is reproduced, since it is capable of supporting the medium voltages and of being able to operate in the range of medium voltages. Typically, the operation of the high-voltage transistors is not optimized for the medium-voltage range, and furthermore, the bulk of the high-voltage transistors is excessive for the medium-voltage range and irreducible. Indeed, to support high voltages, the high-voltage transistors typically include extended conduction regions under their gates, and the minimum gate length of the high-voltage transistors cannot be reduced without introducing short-channel parasite effects.

Thus, there is a need to provide techniques for manufacturing transistors adapted for a particular range of voltages, optimized in their operation, compact and at lesser cost.

### SUMMARY

According to one aspect, in this respect a method is proposed for manufacturing an integrated circuit including a manufacturing of a first transistor for a first range of voltages, comprising: forming a first gate region on a front face of a semiconductor substrate and having sides perpendicular to the front face; depositing dielectric layers accumulating on the sides of the first gate region so as to form regions of spacers having a width in a direction perpendicular to the sides of the first gate region etching to remove a part of the dielectric layers accumulated on the sides of the first gate region so as to reduce the width of the regions of spacers; performing a first step of implantation of dopants aligned on the regions of spacers to form first lightly doped conduction regions of the first transistor; and performing a second step of implantation of dopants to form first conduction regions of the first transistor that are more strongly doped than the lightly doped conduction regions.

Indeed, typically in a manufacturing of an integrated circuit including several transistors configured for operation in several respective ranges of voltages, the deposition of dielectric layers so as to form regions of spacers will accumulate on the sides of all the gate regions that are already formed on the front face.

However, in the method according to this aspect, it is proposed to specifically remove a part of the dielectric layers accumulated on the sides of the first gate region, so as to reduce the width of the regions of spacers. By reducing the width of the regions of spacers of the first transistor, the zones of implantation of the first lightly doped conduction regions are moved closer to the channel region of the first transistor. It is considered that the channel region of the transistor is located in the semiconductor substrate, facing the first gate region. And, by moving said first lightly doped conduction regions closer to the channel region of the transistor, on the one hand the phenomena of ionization by impact engendering “hot carriers” degrading the transistor are reduced, and on the other hand the threshold voltage of the transistor is parameterized in conjunction with the conditions of the first step of implantation of dopants, for optimized performance in the first range of voltages.

Moreover, the term “lightly doped conduction regions” usually used in its form “Lightly Doped Drain/Source” is perfectly known to a person skilled in the art, and designates a region typically implanted less deeply than the conduction region, with a typically lesser concentration of dopants. The source and drain regions of the transistor include the lightly doped conduction regions and the more strongly doped conduction regions.

For example, the first lightly doped regions according to this aspect can have a concentration of dopant species between 10¹⁶ at/cm³ and 10¹⁸ at/cm³ (atoms per cubic centimeter), and a depth between 100 nm and 500 nm (nanometers), while the first more strongly doped conduction regions can have a concentration of dopant species between 10¹⁸ at/cm³ and 10²⁰ at/cm³, and a depth between 100 nm and 500 nm.

According to one embodiment: said depositions of dielectric layers include a step of depositing dielectric layer(s) before said etching step and at least one other step of depositing dielectric layer(s) after said etching step; wherein said etching step is configured to remove the dielectric layer(s) deposited during the earlier step.

Alternatively, the etching step could also be implemented after the depositions of all the dielectric layers, so as to reduce the width of the regions of spacers by the exterior. That being said, the embodiment defined above has the advantage of having a better tolerance in terms of alignment than its alternative, and even of not being constrained at all in terms of alignment.

According to one embodiment, the step of depositing dielectric layers before the etching step includes a deposition of a superposition of conformal layers of silicon oxide, of silicon nitride, and of silicon oxide.

According to one embodiment, the method includes a manufacturing of a second transistor for a second range of voltages comprising: forming a second gate region on the front face of the semiconductor substrate and having sides perpendicular to the front face; performing the same depositing of dielectric layers to form regions of spacers on the sides of the second gate region; and masking configured to prevent said removal, during the etching step, of a part of the accumulations of dielectric layers deposited on the sides of the second gate region.

Thus, the accumulations of dielectric layers of the regions of spacers of the first transistor and of the second transistor have the same constitutions and the same thicknesses, and the second transistor further includes at least one dielectric layer (said part, the removal of which is prevented by the masking step) in said accumulation that is not in the spacer regions of the first transistor.

According to one embodiment, the method includes a manufacturing of a third floating-gate transistor comprising: the same steps of forming the first gate region to form the floating gate of the third floating-gate transistor, comprising: forming a tunnel dielectric layer on the front face; and forming an electrically conductive layer on the tunnel dielectric layer.

This allows, in particular, to benefit from a first gate region having a dielectric layer and a conductive layer well configured for the first voltage range, while being free because of the cointegration with the manufacturing of the third transistor.

According to one embodiment, the method includes a manufacturing of a fourth transistor for a fourth range of voltages comprising: the same first step of implantation of dopants to form fourth lightly doped conduction regions of the fourth transistor.

This allows in particular to benefit from first lightly doped conduction regions, having the same constitution and the same depth as the fourth lightly doped conduction regions, well adapted for the first voltage range, while being free because of the cointegration with the manufacturing of the fourth transistor.

According to one embodiment, the method includes a manufacturing of a fourth transistor configured for operation in a fourth range of voltages comprising: the same etching step removing a part of the dielectric layers accumulated on the front face of the semiconductor substrate.

Here again, given that the manufacturing of the fourth transistors provides an etching step to remove deposited dielectric layers, the cointegrated implementation of the etching step reducing the width of the regions of spacers of the first transistor is free.

According to another aspect, an integrated circuit is proposed including a first transistor configured for operation in a first range of voltages, and a second transistor configured for operation in a second range of voltages; the first transistor including a first gate region and the second transistor including a second gate region, the first and second gate regions being located on a front face of a semiconductor substrate and having sides perpendicular to the front face, and each of the first and second gate regions comprising a conductive layer having the same constitution and the same thickness, typically taken in a direction perpendicular to the front face; the first transistor and the second transistor including an accumulation of dielectric layers having the same constitutions and the same thicknesses on the sides of the first and second gate regions, respectively, so as to form regions of spacers having, respectively, a first width and a second width in a direction perpendicular to the sides of the gate regions; wherein the first transistor includes, in the semiconductor substrate, first lightly doped conduction regions aligned on the regions of spacers, and first more strongly doped conduction regions; and wherein the second transistor further includes at least one additional dielectric layer in said accumulation so as to form regions of spacers having a second width greater than the first width of the regions of spacers of the first transistor.

According to one implementation, the integrated circuit further include a third floating-gate transistor including a floating-gate region comprising a tunnel dielectric layer on the front face and, on the tunnel dielectric layer, a conductive layer having the same constitution and the same thickness as the conductive layer of the first gate region and of the second gate region, wherein the first gate region includes a dielectric layer on the front face having the same constitution and the same thickness as the tunnel dielectric layer.

According to one implementation, the integrated circuit further includes a fourth transistor configured for operation in a fourth range of voltages comprising, in the semiconductor substrate, fourth lightly doped conduction regions having the same constitution and the same depth as the first lightly doped conduction regions.

### BRIEF DESCRIPTION OF THE DRAWINGS

Other advantages and features of the invention will appear upon examination of the detailed description of embodiments and implementations, in no way limiting, and of the appended drawings, in which:

FIGS. 1 to 12 illustrate results of steps of a method for manufacturing an integrated circuit comprising a first transistor (configured for operation in a first range of voltages), a second transistor (configured for operation in a second range of voltages), a third floating-gate transistor (typically configured for a non-volatile memory cell), and a fourth transistor (configured for operation in a fourth range of voltages);

FIG. 13 schematically illustrates a magnification of a spacer region of an implementation of a high-voltage transistor; and

FIG. 14 schematically illustrates a magnification of a spacer region of an implementation of a medium-voltage transistor.

### DETAILED DESCRIPTION

FIGS. 1 to 12 illustrate results of steps of an example of a method for manufacturing an integrated circuit comprising a first transistor GP configured for operation in a first range of voltages, a second transistor HV configured for operation in a second range of voltages, a third floating-gate transistor NVM typically adapted for a non-volatile memory cell, a fourth transistor SRAM, GO1 configured for operation in a fourth range of voltages.

“Transistor” means “at least one transistor”.

The first transistor GP is manufactured in a manner completely cointegrated with the steps of manufacturing the second transistor HV, the third transistor NVM and the fourth transistor SRAM, GO1, that is to say without any manufacturing step dedicated to the first transistor GP.

For example, the first range of voltages, called “medium-voltage”, comprises voltages lower than 5.7V (volts), thus the first transistor GP will be called “medium-voltage transistor”; the second range of voltages, called “high-voltage”, comprises the voltages lower than 10V, thus the second transistor HV will be called “high-voltage transistor”; the fourth range of voltages, called “low-voltage”, comprises the voltages lower than 1.4V, thus the fourth transistor SRAM, GO1 will be called “low-voltage transistor”.

The fourth transistor SRAM, GO1 is illustrated according to two possible cases, one corresponding to a transistor SRAM manufactured for a static random-access memory, the other corresponding to a transistor GO1 manufactured for a logic circuit such as a state machine or a processor. In certain technologies, the static random-access memory transistors SRAM and the logic transistors GO1 are identical, in other technologies, the static random-access memory transistors SRAM and the logic transistors GO1 have slight differences, in particular in terms of lightly doped conduction region LDD0, LDD1 (see below in relation to FIGS. 10 and 11). In both cases, it will be considered in the sense of the cointegration of the first transistor GP that the fourth transistor is one or the other of the transistors SRAM, GO1.

Finally, even though the manufacturing of the medium-voltage transistor GP is described in a context entirely cointegrated with the steps of manufacturing the second transistor HV, third transistor NVM and fourth transistors SRAM, GO1, embodiments partly cointegrated with, for example, only one or two of the second transistor HV, third transistor NVM and fourth transistor SRAM, GO1 are included in the present description by considering the corresponding steps as being implemented in a dedicated manner for the manufacturing of the medium-voltage transistor GP.

FIG. 1 illustrates the result of a step 100 in which lateral isolation regions STI, for example shallow insulation trenches, have been formed in a semiconductor substrate PSUB, in order to define active regions with respect to each other in the substrate PSUB, in a conventional manner known per se. The substrate PSUB is typically made of p-doped crystalline silicon. Alternatively, the substrate PSUB can be n-doped, in which case a person skilled in the art will be able to adapt the type of doping of the wells and of the respective conduction regions in the manufacturing method described below. The face of the substrate PSUB on which the manufacturing steps are carried out is called front face FA.

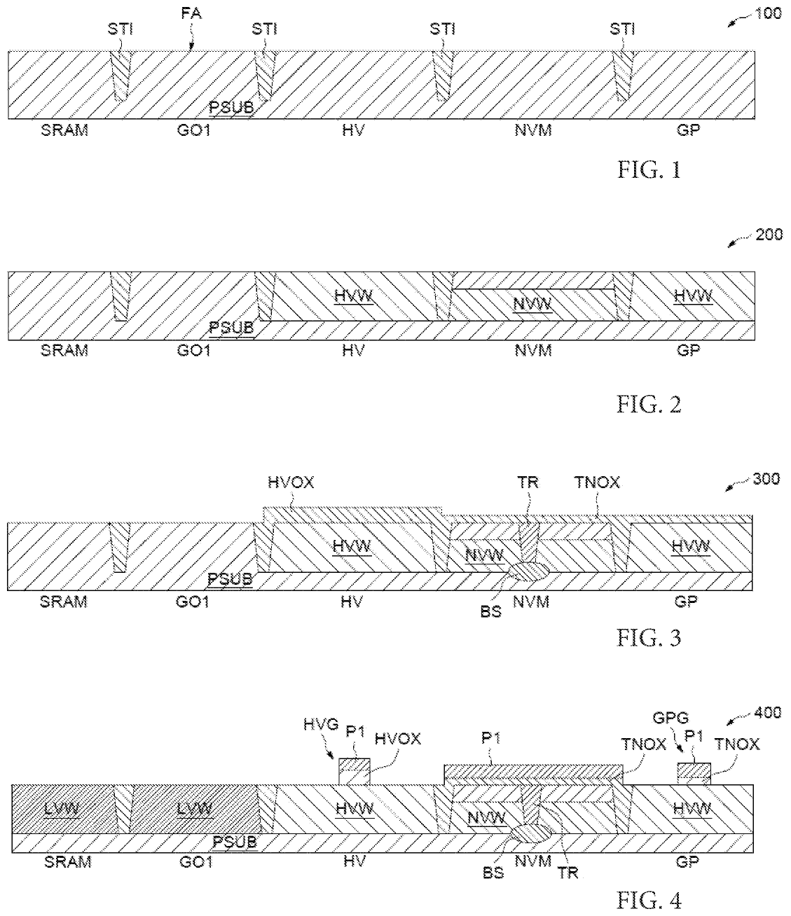

FIG. 2 illustrates the result of a step 200 of forming “high-voltage” wells HVW, by implantation of dopants, in the active region housing the high-voltage transistor HV and in the active region housing the medium-voltage transistor GP. The step 200 further comprises a formation of a well NVW specific to the non-volatile memory in the active region housing the floating-gate transistor NVM. The well of the non-volatile memory NVW includes in particular a buried isolation well and contact wells (not shown) to form an isolation structure of the “triple well” type (well known to a person skilled in the art) and a surface counter-implant region at the front face FA in order to adjust the threshold voltage of the floating-gate transistor NVM.

FIG. 3 illustrates the result of steps 300, comprising a manufacturing of a vertical-gate buried access transistor TR in the active region housing the floating-gate transistor NVM, including a buried source region BS reaching the buried isolation well (not shown). The steps 300 further comprise a formation of a thick layer of oxide HVOX on the front face FA in the active regions housing the high-voltage transistor HV, the floating-gate transistor NVM, and the medium-voltage transistor GP, followed by a partial etching of the thick layer of oxide HVOX in the active regions housing the floating-gate transistor NVM and the medium-voltage transistor GP, so as to reduce its thickness to a “tunnel” thickness TNOX. The tunnel thickness TNOX is, in particular, configured to support injections of electric charges through it TNOX by Fowler-Nordheim effect, called “tunnel effect”, provided for the writing of data in the non-volatile memory.

FIG. 4 illustrates the result of steps 400 comprising a deposition of a conductive layer P1, typically including polycrystalline silicon, on the entire front face FA of the semiconductor substrate PSUB. An etching is then implemented, typically by photolithography, of the conductive layer P1 and of the layers of oxide HVOX, TNOX so as to on the one hand define the gate region HVG of the high-voltage transistor and the gate region GPG of the medium-voltage transistor GP. The definition of the gate regions HVG, GPG comprises a definition of the sides of the gate regions, in a vertical plane, that is to say perpendicular to the front face FA.

The etching allows on the other hand to remove the conductive layer P1 of the active regions housing the low-voltage transistors SRAM, GO1. The etching is further configured to leave the active region housing the floating-gate transistor NVM entirely covered by the layer of tunnel oxide TNOX and the conductive layer P1.

Moreover, the steps 400 comprise a formation of “low-voltage” wells LVW, by implantation of dopants, in the active regions housing the low-voltage transistor SRAM, GO1. For example, the wells LVW of the low-voltage transistors SRAM, GO1 are formed by the same step of implantation of dopants.

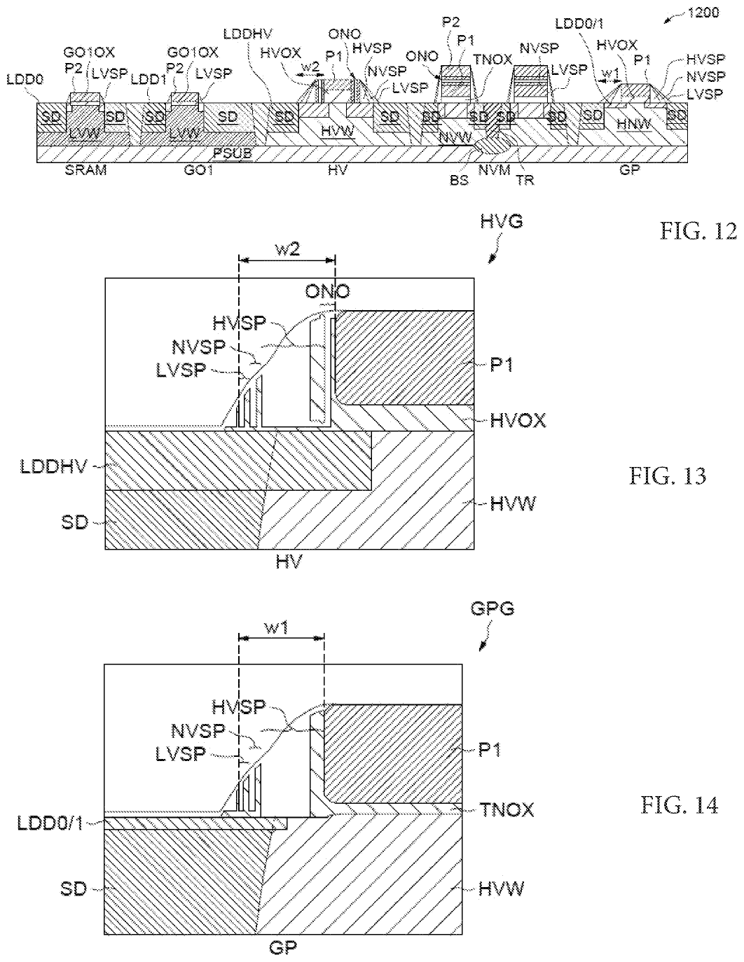

FIG. 5 illustrates the result of first steps of depositions of dielectric layers ONO accumulating on the sides of the gate region GPG of the medium-voltage transistor GP and on the sides of the gate region HVG of the high-voltage transistor HV. The dielectric layers thus accumulated are intended to form regions of spacers having a second width w2 (for the high-voltage transistor HV, see FIG. 12) in a direction perpendicular to the sides of the gate regions GPG, HVG.

These first deposition steps 500 include a deposition of a superposition ONO of conformal layers of silicon oxide O, of silicon nitride N, and of silicon oxide O on the entire structure obtained after the preceding steps 400. The layers are conformal in that they conform to the horizontal surfaces (for example the front face FA) and the vertical surfaces (for example the sides of the gates GPG, HVG) with a constant thickness (isotropic). An etching step 510 is configured to remove the superposition of dielectric layers ONO deposited on the front face FA in the regions housing the low-voltage transistors SRAM, GO1, and in the region housing the medium-voltage transistor GP. Thus, the etching step 510 removes a part of the dielectric layers ONO accumulated on the sides of the first gate region so as to reduce the width w1 of the regions of spacers, in fine (for the medium-voltage transistor GP, see FIG. 12).

The superposition of dielectric layers ONO is not removed in the regions housing the high-voltage transistor HV and the floating-gate transistor NVM, for example via a step of masking 505 covering and protecting from the etching the high-voltage region HV and the memory region NVM.

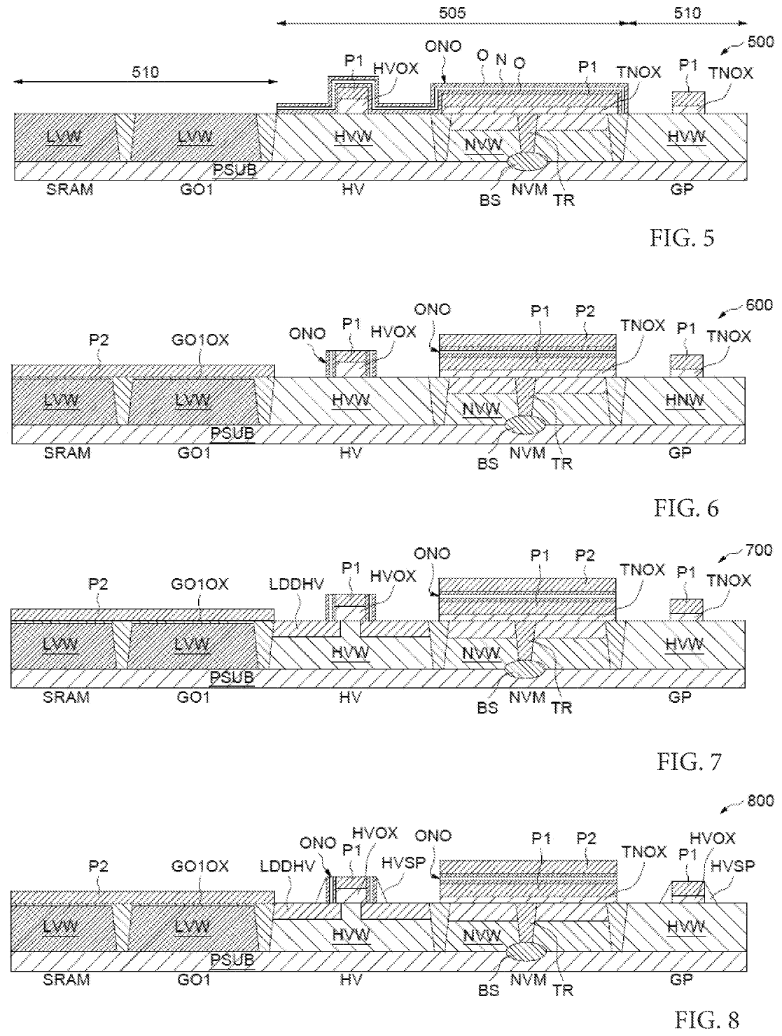

FIG. 6 illustrates the result of steps 600 comprising on the one hand a formation of a layer of gate oxide GO1OX on the front face FA in the active regions of the low-voltage transistors SRAM, GO1.

On the other hand, the steps 600 comprise a deposition of a second conductive layer P2 on the entire structure obtained after the preceding steps 500, GO1OX, and a directional etching configured to remove the second conductive layer P2 in the region of the high-voltage transistor HV, and in the region of the medium-voltage transistor GP.

The directional etching is further configured to remove, in the region of the high-voltage transistor HV, the superposition of dielectric layers ONO deposited on horizontal surfaces (parallel to the front face FA) and to not remove, or remove a minority of, the superposition of dielectric layers ONO deposited on vertical surfaces (perpendicular to the front face FA).

FIG. 7 illustrates the result of step 700 in which lightly doped conduction regions LDDHV are implanted in the well HVW of the high-voltage transistor HV only. The implantation of the lightly doped conduction regions LDDHV is, for example, self-aligned on the superposition of dielectric layers ONO in terms of width on the sides of the gate region HGV of the high-voltage transistor HV.

In particular, the lightly doped conduction regions LDDHV are not implanted in the well HWV of the medium-voltage transistor GP, for example via a mask blocking the implantation in the active region of the medium-voltage transistor GP.

FIG. 8 illustrates the result of a step 800 of deposition of one or more dielectric layer(s) HVSP accumulating on the sides of the gate regions HVG, GPG of the high-voltage transistor HV and of the medium-voltage transistor GP, so as to form, in particular, the regions of spacers of these transistors.

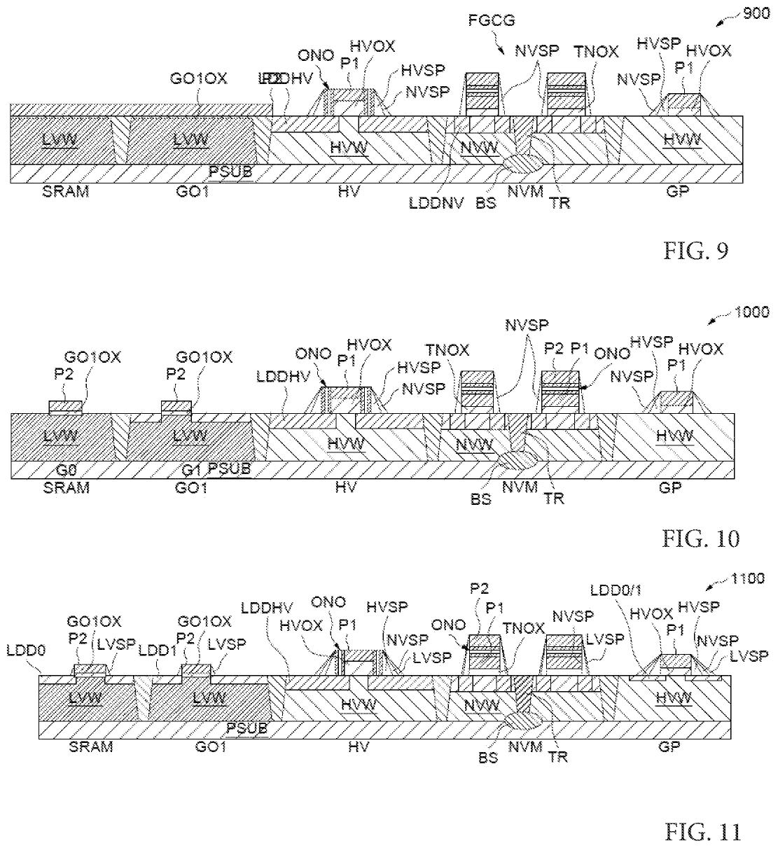

FIG. 9 illustrates the result of steps 900 comprising an etching in the region of the floating-gate transistor NVM, typically by photolithography, so as to define the gate region FGCG of the floating-gate transistor NVM. The etching is configured to etch the stack of the second conductive layer P2, of the superposition of dielectric layers ONO, of the first conductive layer P1 and of the layer of tunnel oxide TNOX. The gate region FGCG of the floating-gate transistor NVM thus includes a floating gate P1 located between the layer of tunnel oxide TNOX and a control gate P2, the floating gate P1 and the control gate P2 being electrically isolated by the superposition of dielectric layers ONO. An implantation of lightly doped conduction regions LDDHV are implanted in the well NVW of the floating-gate transistor NVM only. The implantation of the lightly doped conduction regions LDDHV is, for example, self-aligned on the gate region FGCG of the floating-gate transistor NVM.

Moreover, the steps 900 comprise a deposition of one or more dielectric layer(s) NVSP additionally accumulating on the sides of the gate regions FGCG, HVG, GPG of the floating-gate transistor NVM, of the high-voltage transistor HV, and of the medium-voltage transistor GP, so as to form, in particular, the regions of spacers of these transistors.

FIG. 10 illustrates the result of steps 1000 comprising an etching in the region of the low-voltage transistor SRAM, GO1, typically by photolithography, so as to define the gate region G0, G1 of the low-voltage transistors SRAM, GO1. The etching is configured to etch the stack of the second conductive layer P2 and of the layer of gate oxide GO1OX.

The distinction between the static random-access memory cell low-voltage transistor SRAM and the logic circuit low-voltage transistor GO1 is now made.

In a first case, the implantation of the lightly doped conduction regions LDD1 of the logic circuit low-voltage transistor GO1 and the implantation of the lightly doped conduction regions LDD0 of the static random-access memory cell low-voltage transistor SRAM are carried out in distinct steps 1000 and 1100.

In a second case, the implantation of the lightly doped conduction regions LDD1 of the logic circuit low-voltage transistor GO1 and the implantation of the lightly doped conduction regions LDD0 of the static random-access memory cell low-voltage transistor SRAM are carried out in the same single step 1000 or 1100.

In the first case, the lightly doped conduction regions LDD1 of the logic circuit low-voltage transistor GO1 are implanted in the steps 1000, for example in a manner self-aligned on the gate region G1 of the logic circuit low-voltage transistor GO1.

In a first alternative of the second case, the lightly doped conduction regions LDD0 of the static random-access memory cell low-voltage transistor SRAM and the lightly doped conduction regions LDD0/1 of the medium-voltage transistor GP are implanted at the same time and in the same manner as the lightly doped conduction regions LDD1 of the logic circuit low-voltage transistor GO1 in the steps 1000.

FIG. 11 illustrates the result of steps 1100 comprising a deposition of one or more dielectric layer(s) LVSP on the sides of the gate regions G0, G1 of the low-voltage transistors SRAM, GO1, and also accumulating on the sides of the gate regions of the high-voltage transistor HV, of the floating-gate transistor NVM, and of the medium-voltage transistor GP, so as to finalize the formation of the regions of spacers of these transistors.

In the first case mentioned above, the steps 1100 comprise an implantation of the lightly doped conduction regions LDD0 of the static random-access memory cell low-voltage transistor SRAM, for example in a manner self-aligned on the spacer region LVSP on the sides of the gate G0 of the low-voltage transistor SRAM.

According to a preferred embodiment, the lightly doped conduction regions LDD0/1 of the medium-voltage transistor GP are implanted at the same time and in the same manner as the lightly doped conduction regions LDD0 of the static random-access memory low-voltage transistor SRAM in the steps 1100 of the first case, in particular in a manner self-aligned on the spacer region LVSP, NVSP, HVSP on the sides of the gate GPG of the medium-voltage transistor GP.

In a second alternative of the second case, the lightly doped conduction regions LDD1 of the logic circuit low-voltage transistor GO1 and the lightly doped conduction regions LDD0/1 of the medium-voltage transistor GP are implanted at the same time and in the same manner as the lightly doped conduction regions LDD0 of the static random-access memory low-voltage transistor SRAM in the steps 1100.

FIG. 12 illustrates the result of steps 1200 comprising an implantation of dopants forming conductive regions SD of all the transistors SRAM, GO1, HV, NVM, GP of the circuit. The implantation 1200 is, for example, self-aligned on the regions of spacers of each transistor SRAM, GO1, HV, NVM, GP comprising respective accumulations of dielectric layers ONO, HVSP, NVSP, LVSP on the sides of the corresponding gate regions G0, G1, HVG, FGCG, GPG. The conduction regions SD are implanted more deeply in the substrate PSUB and with a greater concentration of dopants than the lightly doped conduction regions LDD0, LDD1, LDDHV, LDDNV, LDD0/1.

In particular, the accumulations of dielectric layers HVSP, NVSP, LVSP on the sides of the first gate region GPG of the first transistor GP form the regions of spacers having a first width w1 in the direction perpendicular to the sides of the first gate region GPG, and the accumulations of dielectric layers ONO, HVSP, NVSP, LVSP on the sides of the gate region HVG of the high-voltage transistor HV form the regions of spacers having a second width w2 in the direction perpendicular to the sides of the first gate region GPG.

Reference is made in this respect to FIGS. 13 and 14.

FIG. 13 schematically illustrates a magnification of a spacer region of an implementation of a high-voltage transistor HV as described above in relation to FIGS. 1 to 12.

FIG. 14 schematically illustrates a magnification of a spacer region of an implementation of a medium-voltage transistor GP as described above in relation to FIGS. 1 to 12.

In these implementations, in the same integrated circuit, the medium-voltage transistor GP and the high-voltage transistor HV include respective gate regions GPG, HVG comprising a conductive layer P1 having the same constitution and the same thickness, given that the conductive layers P1 were formed during the same steps 400.

Moreover, the medium-voltage transistor GP and the high-voltage transistor HV include, in their respective regions of spacers on the sides of their gate regions P1, an accumulation of dielectric layers HVSP, NVSP, LVSP having the same constitutions and the same thicknesses, forming the whole spacer regions of the medium-voltage transistor GP having a first width w1.

Given that in the method for joint (cointegrated) manufacturing of the medium-voltage transistor GP and of the high-voltage transistor HV at least one dielectric layer (ONO) of the accumulation was removed (step 510) for the medium-voltage transistor, the high-voltage transistor HV includes said at least one additional dielectric layer ONO in the accumulation on the sides of its gate P1, so as to form whole regions of spacers having a second width w2 greater than the first width w1.

In the example described in relation to FIGS. 1 to 12, said at least one “additional” dielectric layer—present in the accumulation of dielectric layers forming the spacer region of the high-voltage transistor GP, and absent in the accumulation of dielectric layers forming the spacer region of the medium-voltage transistor GP—is the superposition ONO of layers of oxide, of nitride and of oxide of silicon.

That being said, in other examples, said at least one “additional” dielectric layer could be at least one of the other dielectric layers of the accumulation of dielectric layers forming the spacer region of the high-voltage transistor HV, such as the dielectric layers HVSP, NVSP, LVSP, or other dielectric layers that were not mentioned or shown in relation to FIGS. 1 to 12.

Moreover, the medium-voltage transistor GP and the high-voltage transistor HV include lightly doped conduction regions LDD0/1, LDDHV implanted in the wells HVW, and more strongly doped conduction regions SD. The source and drain regions of the transistors GP, HV each incorporate a lightly doped conduction region LDD0/1, LDDHV and a more strongly doped conduction region SD.

The lightly doped conduction regions LDDHV of the high-voltage transistor HV extend in the channel region of the transistor HV, that is to say under the gate region HVG facing the conductive layer P1. This allows to ensure the voltage withstanding of the high-voltage transistor HV but imposes a significant gate length.

The lightly doped conduction regions LDD0/1 of the medium-voltage transistor GP do not extend until the channel region of the transistor GP, and are located under the regions of spacers.

However, since a part of the dielectric layers (ONO) accumulated on the sides of the gate region GPG of the medium-voltage transistor GP were removed, the lightly doped conduction regions LDD0/1 were moved closer to the channel region of the medium-voltage transistor GP. It is considered that the channel region of the transistor is located in the well HVW, facing the gate region P1. This allows on the one hand to reduce the phenomena of ionization by impact engendering “hot carriers” degrading the transistor, and on the other hand to have a threshold voltage adapted for optimized performance in the range of medium voltages, that is to say for example less than 5.7V.

1. A method for manufacturing an integrated circuit, comprising:
manufacturing a first transistor configured for operation in a first range of voltages, comprising:
forming a first gate region on a front face of a semiconductor substrate, said first gate region having sides perpendicular to the front face;
depositing dielectric layers accumulating on the sides of the first gate region so as to form regions of spacers having a width in a direction perpendicular to the sides of the first gate region;
etching to remove a part of the deposited dielectric layers which accumulated on the sides of the first gate region so as to reduce a width of the regions of spacers;
a first implanting of dopants aligned on the regions of spacers to form first lightly doped conduction regions of the first transistor; and
a second implanting of dopants forming first conduction regions of the first transistor, where said first conduction regions are more strongly doped than the lightly doped conduction regions.

2. The method according to claim 1:
wherein depositing dielectric layers comprises first depositing one or more dielectric layers before etching to remove and second depositing one or more dielectric layers after etching to remove;
wherein etching to remove comprises removing one or more dielectric layers which were deposited in the first depositing.

3. The method according to claim 2, wherein the first depositing comprises depositing a superposition of conformal layers of silicon oxide, silicon nitride, and silicon oxide.

4. The method according to claim 1, further comprising manufacturing a second transistor configured for operation in a second range of voltages comprising:
forming a second gate region on the front face of the semiconductor substrate, said second gate region having sides perpendicular to the front face;
wherein the depositing dielectric layers further forms regions of spacers on the sides of the second gate region; and
masking to prevent removal, as a result of said etching to remove, of a part of the accumulations of dielectric layers deposited on the sides of the second gate region.

5. The method according to claim 1, further comprising manufacturing a third floating-gate transistor:
wherein forming the first gate region also forms a floating gate of the third floating-gate transistor;
the method further comprising:
forming a tunnel dielectric layer on the front face; and
forming an electrically conductive layer on the tunnel dielectric layer.

6. The method according to claim 1, further comprising manufacturing a fourth transistor configured for operation in a fourth range of voltages:
wherein said first implanting of dopants further forms fourth lightly doped conduction regions of the fourth transistor.

7. The method according to claim 1, further comprising manufacturing a fourth transistor configured for operation in a fourth range of voltages:
wherein etching to remove further removes a part of the dielectric layers accumulated on the front face of the semiconductor substrate.

8. An integrated circuit, comprising:
a first transistor configured for operation in a first range of voltages;
a second transistor configured for operation in a second range of voltages;
wherein the first transistor includes a first gate region and the second transistor including a second gate region;
wherein the first and second gate regions are located on a front face of a semiconductor substrate;
wherein each of the first and second gate regions has sides perpendicular to the front face and a conductive layer having a same constitution and a same thickness;
wherein the first transistor and the second transistor each include an accumulation of dielectric layers having same constitutions and same thicknesses on the sides, said accumulations of dielectric layers forming regions of spacers having, respectively, a first width and a second width in a direction perpendicular to the sides;
wherein the first transistor includes, in the semiconductor substrate, first lightly doped conduction regions aligned on the regions of spacers and first more strongly doped conduction regions;
wherein the second transistor includes at least one additional dielectric layer in said accumulation than the dielectric layers in the accumulation for the first transistor, regions of spacers for the second transistor having a second width greater than a first width of the regions of spacers of the first transistor.

9. The integrated circuit according to claim 8, further comprising:
a third floating-gate transistor including a floating-gate region with a tunnel dielectric layer on the front face and a conductive layer on the tunnel dielectric layer that has a same constitution and a same thickness as the conductive layer of the first gate region and the second gate region;
wherein the first gate region includes a dielectric layer on the front face having a same constitution and a same thickness as the tunnel dielectric layer.

10. The integrated circuit according to claim 9, further comprising:
a fourth transistor configured for operation in a fourth range of voltages;
said fourth transistor including, in the semiconductor substrate, fourth lightly doped conduction regions having a same constitution and a same depth as the first lightly doped conduction regions.
